(19) United States
(12) Patent Application Publication
(10) Pub. No.: US 2022/0246350 A1
(43) Pub. Date: Aug. 4, 2022

(54) Current Transformer with Optic Fiber Mode Electronic Circuit

(71) Applicant: Narayan Powertech Pvt. Ltd., Vadodara (IN)

(72) Inventor: Sandip Shah, Vadodara (IN)

(21) Appl. No.: 17/441,979

(22) PCT Filed: Mar. 22, 2019
(86) PCT No.: PCT/IB19/00330

§ 371 Date: Sep. 22, 2021

(51) Int. Cl. H01F 27/42; G01R 35/02; H01F 38/32; G01R 15/18

(52) U.S. Cl. CPC H01F 27/427; G01R 15/183; H01F 38/32; G01R 35/02

(57) ABSTRACT

The current transformer system that is the present invention allows for surveillance of an electronic grid at electrical power generating stations, at individual operational substations and in electric power distribution for electric network and grid measurement, protection, and control ranging from very low currents to high current magnitudes. The reception and relay of information from the CT primary circuit is sensed and transmitted by a primary electronic circuitry, digitized, converted to a fiber optic mode, transmitted to a secondary electronic circuit, processed and converted to a digital output and transmitted to various monitoring and recording devices.

### FIELD OF THE INVENTION

The present invention relates to a device and method of use to detect and monitor the primary alternating current (AC) output of an electrical power system through a current transformer (CT), generally, and to the detection of the output of a secondary winding, as a function of the primary winding, through a fiber optic conveyance, specifically. The reception and relay of information from the CT primary circuit, via the secondary winding, is sensed by electronic circuitry, converted to a fiber optic mode, transmitted through a fiber optic conveyance through the transformer bushing, decoded by electronic circuitry and converted to a digital output which is then reported to various monitoring and recording devices. The current system allows for surveillance of an electronic grid at electrical power generating stations, at individual operational substations and in electric power distribution for electric network and grid measurement, protection, and control from very low current to a high current range.

### DESCRIPTION OF THE RELATED ART

Electronic metering and monitoring of electrical energy, wherein current transformers (CT) create indirect readings through reduction of high voltage currents to low voltage currents, is accomplished via voltage lowering secondary windings relative to a high current facilitating primary winding as measured by ammeters. Current transformers consist of three basic configurations: Wound current transformers, toroidal (window type) transformers and bus-bar type transformers. Wound current transformers are physically connected in series with the conductor carrying the measured current flow. In the case of a window-type current transformer, an opening is provided wherein a primary current carrying line passes through a window or “air core” created through a toroidal transformer, about which the secondary coil is affixed, thereby detecting the primary current as it passes through the window or “air core”. Finally, the bus-bar type current transformer utilizes the cable or bus-bar of the main circuit as the primary winding and it is generally in direct connection to the current carrying device. In each transformer design, by decreasing the voltage from the primary conductor responsible for carrying the primary current into the secondary winding, the current transformer (CT) is utilized to provide an efficient and safe way to monitor, analyze and control the electrical current flowing in a transmission line.

The current transformer itself is comprised of a primary winding (configured to carry a primary current) that consists of one to a small number of ‘turns’ in its primary winding which is contrasted by a secondary winding (exhibiting a larger number of coil turns) that is typically wound on a laminated core of low-loss magnetic material. The current transformer core, consisting of a large cross-sectional area, insures that the magnetic flux density created is low which uses smaller cross-sections that are dependent upon the degree of current reduction in the form of “stepping down” the current from, in most cases, thousands of amperes down to a standard output of about 1 to 5 amps for normal operation (i.e. current transformation). By reducing amperes to a manageable current, instruments and control units (e.g. ammeters) can be used to accurately monitor current with requisite sensitivity, due to the insulated separation from high-voltage power lines, without fear of overloading inherently delicate devices. There are a variety of metering applications and uses for current transformers such as with Wattmeter's, power factor meters, watt-hour meters, protective relays and as trip coils in magnetic circuit breakers (MCB's).

In AC circuits, a current transformer converts the magnetic field around a conductor into a small AC current, typically either 1 A or 5 A (as recounted above), from a full rated current, that can be easily read by a meter (i.e. a linked or detached ammeter). The majority of these ammeters are either connected in series (with the circuit carrying the current to be measured) or have a shunt resistor, similarly connected in series, where current passes through the meter or through its shunt for current “reading”. Moreover, ammeters are purposefully not connected directly to a voltage source since their internal resistance is very low and excess current flow would cause untoward damage to these delicate instruments. Typically, ammeters are designed for a low voltage drop across their terminals, much less than one volt, where the extra circuit losses produced by the ammeter are expressed as its “burden” on the measured circuit.

Most relevant to the present invention, the majority of current transformers in use today are typically aligned to one of two basic designs: ‘Live Tank Type Designs’ and ‘Dead Tank Type Designs’. The ‘Live Tank Type Design’ being defined by the placement of the core and secondary wiring in an elevated state above the ground (i.e. in the Live (High Voltage) tank or top housing). In opposite, the ‘Dead Tank Type Design’ is marked by a CT core and secondary winding residing close to ground (or at ground level) at an earth potential (i.e. in the ‘Dead (Earthed) Tank’ or ‘Bottom Housing’). Given to all practical considerations, though, the benefits of a ‘Live Tank Design’ is generally superior (i.e. the ‘Live Tank Design’ having considerable advantages) to the ‘Dead Tank Design’ and therefore can be seen as a pragmatic selection when factoring in the following: application of insulation (simple in live tank designs versus difficult with dead tank designs), condenser grading (easily accomplished in a live tank design), robustness and reliability of insulation (superior in a live tank design), length of primary winding and its effects on insulation requirements/heat generated during short time thermal current (increasing length and current traversing of the insulated area leading to excess heat generation and untenable slow heat dissipation in the ‘Dead Tank Design’), relative size and overall cost (dead tank designs being larger, bulkier, requiring more insulation and resultantly costlier implementation and operation, due to the aforementioned explanations).

It is therefore the long-felt and unaddressed need of the ability of a novel current transformer for power plant, substation and grid power measurement, protection, maintenance and control capable to measure currents ranging (1) from very low current magnitudes to high current magnitudes where (2) current measurement offers a more precise “reading” of the primary circuit (unaffected by magnetic saturation or magnetic remanence/residual magnetism). Likewise, the present invention that is the Current Transformer (CT) (3) allows for enhanced protected metering with (4) decreased safety issues inherent in large, bulky power current CT devices which (5) relieves the burden of large volume and weight materials (e.g. aluminum, copper, bulky insulation and transformer oil) thus alleviating weight, cost and untoward environmental concerns. Further, the smaller size and (6) endlessly flexible configurations and arrangements of fiber optics, as opposed to the analog equipment, allows for an (7) easily integrated monitoring and metering system (into new and existing current transformers) that is (8) lighter, more compact and in less need of structural support which (9) extends the overall safety, utility and lifespan of existing mechanical features. What is more, the proffered current transformer, (10) does not require initial calibration or recalibration over a time period (due to installation and reinstallation (or positioning)) and (11) does not suffer, to such an advanced degree, from a susceptibility of ill effects on internal ecologically sensitive materials environmental exposure to the environment due to outside meteorological disturbances (e.g. climatological events such as high winds, hurricanes, tornados and earthquake). It is this need that the present invention seeks to address.

### SUMMARY OF THE INVENTION

Presently, currents in high-voltage and high current equipment are measured using large and bulky current transformers that utilize electromagnetic induction to transfer energy from a larger primary current to a smaller secondary current. That measurement is subsequently outputted to an ammeter, for receiving and displaying the current “reading” of the primary current, all facilitated through heavily weighted insulation mediums (e.g. oil/gas/thermos plastics/thermoset resins)—all in a strictly analog fashion. Yet, this system, in addition to size and weight, has additional infirmities of magnetic saturation (where magnetic forces further magnetize a material linearly to a point where increases in magnetizing force no longer result in magnetization of a material), inherent mechanical and physical limits in analog measurments and shortcomings in sensitivity (wherein the waveform of the secondary current is inherently not an exact measurement of the primary current).

In addition, the mechanical and physical shortcomings existing in a typical current transformer can give rise to detectible errors in determining the current in the primary winding. Wherein the “ideal” ratio of primary to secondary turns would be represented as an “exact” ratio (that is uniformly equal), the actual ratio is nonetheless imprecise thus resulting in an inherently inexact reading of the primary current. Expressly, magnetomotive forces in an inexact phase and actual (as opposed to ideal) current ratios diverge from “exact” turns ratios resulting in certain divergent phase angles evidenced through both ratio errors and phase angle errors. With relation to ratio error, the secondary winding can be affected by several factors including winding resistance, reactance and the power factor of the burden as determined by the following equation:

Current or Ratio Error=(Nominal ratio−Actual ratio)/Actual ratio=(Kn−R)/R×100

What is more, where an “ideal” current transformer would exhibit a zero-phase angle and the reversed secondary current would be displaced at exactly 180 degrees from the primary current, this is essentially a practical impossibility. In operation, if the current displacement is not at 180 degrees (which is common), the reversed secondary current lags the primary current, the phase displacement is negative, the phase angle is positive, and the result is aberrated data. Certain corrective measures can be introduced in an attempt to minimize error rates (e.g. insuring that exciting or no load current be kept small, assuring that the load angle of the secondary is equally small, confirming that the core should have low core loss and, additionally, minimizing the number of turns in the secondary thereby reducing secondary impedance), but the use of analog measuring equipment and analog measuring devices will always carry with them these inherent deviations and intrinsically induced errors resulting in fundamental digressions from a “true” reading.

Distortions between the primary winding and secondary winding not being the sole problem addressed by the present invention, inherent deviations from the true readings are nonetheless a paramount concern potentiated by the configuration of conventional current transformers wherein the magnetic flux produced by an alternating current in the primary winding causes an reciprocal alternating current in the secondary winding that is then communicated to an ammeter or relay, ultimately, imperfectly. Several influencing factors, though, have the potential to further alter the true reading originating in the primary due to direct influence of voltage created on the high voltage side and the mechanical and physical limitations of each intermediary electronic device. Moreover, upon installation and transference, these variances in output readings must be anticipated and considered and require strictly observed post-installation calibration (as well as subsequent re-calibration). Too, current transformers are typically manufactured to precise ratings wherein a transformer is specifically designed to accommodate narrow varying current magnitudes wherein current transformer may not be equipped to detect a wide range of current magnitudes. Therefore, it is common that one unit cannot serve to vacillate between vastly disparate current ranges used in different primary ratings for different load applications. Too size and weight of customary current transformers constitute a contributory factor addressed herein as these factors lend themselves to the overt loss of utility, safety, cost effectiveness and untoward potential environmental impacts.

The present invention is designed for metering and protection functions in a single current transformer unit which may be utilized in a multitude of ranges from very low current to very high current magnitudes. Functionally, the primary current of a current transformer is (1) first received, (2) interpreted, (3) read “digitally”, via electronic circuitry, typically in the elevated housing of a Live Tank Design (or the grounded housing of the Dead Tank Design) and then (4) conveyed as data to the operator. That conveyance of information has the ability to be transferred to ammeters in more accurate and less physically and mechanically incumbered communications through fiber optics. Clearly, it is this intermediate stage, the transference of information and data, more so than the digital “reading”, that carries with it the aspect most susceptible to distortion and therefore amendable to improvement. The transference of information in the present invention relies on the relationship between light and magmatism wherein the magnitude of a current is a function of light, originally observed by Michael Faraday, based on the interaction between light and a magnetic field in a medium where the rotation of the plane of polarization is linearly proportional to the component of the magnetic field in the direction of propagation. This “Faraday Effect” takes advantage of left and right circularly polarized waves propagating at slightly different speeds (i.e. circular birefringence) and the effect of phase shifting that these waves create. Instead of an indirect reading of the primary current via a representation in the secondary current, an “image” of the primary current is read directly by electronic circuitry thereby resulting in a direct, and therefore a more accurate and analytical, “reading” (i.e. detection) of the primary current. By using this direct detection method and fiber optic conveyance (or plurality of fiber optic conveyances), the transportation of a “representation” of the current is not influenced by mechanical disturbances (as in analog detection circuitry), it offers a more precise “image” of the primary circuit (unaffected by magnetic saturation or magnetic remanence/residual magnetism), allows for protected metering, decreases safety issues inherent in large, bulky power current CT devices, and obviates large volume and weight materials (e.g. aluminum, copper, bulky insulation and transformer oil)—relieving weight, cost and environmental concerns. Further, the smaller size and endlessly flexible configuration and arrangements of fiber optics, as opposed to static analog equipment, allows for an easily integratable monitoring and metering system (into new and existing current transformers) that is lighter, smaller (in the case of individual CTs and, resultantly, substations), in less of need of structural support through greatly reinforced and bolstered foundations, extends the overall lifespan of the mechanical features of a current transformer, does not need initial calibration or recalibration over a time period and does not suffer, to such an advanced degree, from a susceptibility of outside ecological disturbances.

In this present invention, the current transformer can be manufactured such that metering and protection applications are part of single current transformer unit and such single current transformer units can be used to detect very low current to very high current magnitudes, alike, without recalibrating the current transformers. Moreover, this highly accurate data procurement may be accomplished in multiplicity exhibiting the aforementioned diminished error rates, in the case of current transformer combinations for detecting multiple individual circuit currents with one CT, providing negligible abortions across various combinations and configurations measured in sum and further evidencing the potential advantages of the present invention en masse (as opposed to the accumulated error rates experienced in additive traditional CTs where even relatively small aberrations can be compounded into cumulatively larger deviations).

Operably, the output of the secondary winding of a current transformer is received and interpreted by electronic circuitry, harbored in upper portion of the upper “live” tank, which then interprets, digitizes and relays the digitized information, via an optical fiber (or a plurality or series of optical fibers), to a second electronic circuit or electronic circuitry, located in the lower housing of the “live tank” (i.e. the secondary terminal box). This secondary electronic circuitry is responsible for receiving and transmitting the output of the secondary winding (as a function of the primary winding of the current transformer), which then utilizes a RJ-45 type interface, RS-232 type interface, RJ-432 type interface or RS-485 type interface to transmit, or retransmit, the digitized information from the interior of the unit, exteriorly to a computing system located in any one of a number of monitoring or control systems. The output can also be linked to a GSM (Global System for Mobile Communications) to facilitate reciprocal communications with technicians, operators and engineers over digital cellular networks and the like.

By digitizing a representation of the primary circuit through internalized electronic circuitry and transmitting the received information via fiber optics, the signal which is generated and propagated, together with a compatible communication interface, insures not only a clearer “image” of the current in the primary, but also allows for transmittal of information in a digitized format that is exceptional in that the image signal is more representational, conveyable and reproducible over greater lengths than that of any of its analog predecessors. Using this concept, a digital signal is provided directly to an electronic network for measurement, protection, control, sensing, and/or instrumentation conveying purposes. The invention disclosed herein can be equally useful to the manufacture of current transformers with ‘Live Tank’ and ‘Dead Tank’ Designs and for widely varying current types. Where the utility of the output of conventional current transformers lies in analog signals, the novelty of the present invention is in the internal conversion of the analog output of the secondary windings, as a function of the primary winding, into a digital signal which can be relayed accurately, across large distances, is less subject to electromagnetic distortion, requires minimal insulation and may be directly fed into a computer for measuring, interpretation and storage—all cured infirmities of analog reading and transmittal of current readings. Analog-digital-optical-digital signal conversion is accomplished with an integrated electronic circuitry, abutting the fiber optic conveyance, where the primary and secondary windings generate primary and secondary currents that are subsequently digitized and optically transmitted (via an optical fiber cable) through the transformer bushing to the secondary base (terminal box) containing additional electronic circuitry. That secondary electronic circuitry receives and processes the optical signal carried by optical fiber cable and converts the received signal into a digital signal for contemporaneous or timed reception, interpretation, analysis, transmission and storage.

Additionally, the energy source that makes up the auxiliary power supply for the electronic circuitry can be supplied using a conventional battery, connected to a self-powered type rechargeable battery or may be integrated into the existing electrical system or electric grid (via the primary or secondary current) in such a decreased ampere wherein the electronic circuitry can derive its power directly from the power that it is charged with monitoring.

Too, the present invention current transformer, where the CT primary current is sensed, digitized, converted to fiber optic mode, decoded and again transmitted, communicated or recommunicated in the form of digital output, from a very low to a high current range, may be used in both live and dead tank designs. Additionally, the present invention may be used for both AC or DC electrical networks for measurement, protection, and power control with auxiliary supply or self power supply to sensing, communicating and transmitting circuits.

In one preferred embodiment, the present invention may be utilized in existing and newly developed current transformers where retrofitted current transformers and newly designed current transformers benefit alike.

In an additional preferred embodiment, the present invention may be incorporated into a system where a series or combination (i.e. “stacks”) of current transformers are used (e.g. in power stations, transmission substations, distribution substations and entire power grids) where enhanced accuracy may be viewed in aggregate with a cumulative superiority to analog detection and conveyance in current measurement, monitoring, protection, and control.

In another preferred embodiment, the present invention may be an individual current transformer which may be used in series or combination with other individual current transformers or where said individual current transformer may be used to detect, monitor and convey multiple currents simultaneously, contemporaneously or sequentially thereby multiplying the effectiveness of each current transformer's limited error rate in aggregate and in sum.

In another preferred embodiment, individual current transformers may be used in combination, series or parallel wherein each individual CT may contain within their structure a plurality of electronic circuits and/or fiber optic conveyances, in various combinations, evidencing a plurality of electronic circuit and fiber optic conveyance combinations wherein digitized information is transmitted along a fiber optic conveyance, or a multiplicity of fiber optic conveyances, which are easily flexible, modifiable and configurable and amendable to large increases in distance thus allowing for current readings from very low to very high magnitudes, requiring no calibration or recalibration, can accommodate both AC and DC currents, offers current measurements that are more accurate than analog measurements in a configuration that is lighter, more compact, safer, more cost efficient and more environmentally conscious.

In yet another preferred embodiment, the current transformer that is the present invention may utilize the aforementioned electronic curcuits, digitized information and fiber optic conveyances in current sensing, measurement, monitoring, and transmittance of information to an external computer, plurality of computers, or computer system for data collection, interpretation, and analysis but also may utilize the same avenues, retrograde, for instrument diagnostics, control, adjustments, and/or updates where information is sent from an external computer, or plurality of computers, to the current transformer that is the present invention.

The inventor of the present invention recognizes and addresses the above-mentioned insufficiencies and long-felt needs in the art and provides solutions to those problems in various possible embodiments and equivalents thereof. Benefits of the present invention will become apparent to one having skill in the art through this disclosure when taken in combination with the accompanying drawings. While inventor has set forth the best mode or modes contemplated of carrying out the invention known to inventor such to enable a person skilled in the art to practice the present invention, the preferred embodiments are, however, not intended to be limiting, but, on the contrary, are included in a non-limiting sense apt to alterations and modifications within the scope and spirit of the disclosure and appended claims.

### BRIEF DESCRIPTION OF THE DRAWINGS

The advantages and other aspects of the invention will be readily appreciated by those of skill in the art and better understood with reference to the accompanying drawings in which individual features are designated and depicted, alone and in combination with reciprocal elements, throughout the several figures of the drawings.

The figures themselves are merely representational and provide a conceptual interpretation of the present invention and, as such, are not to scale and should not be interpreted as restricting the functional components, advantages and technical advancements of the present invention or to, in any way, surrender equivalents of the present invention or limit the scope the appended claims.

FIG. 1 depicts a diagram illustrating a conventional “live tank” type design current transformer.

FIG. 2 displays a diagram of a traditional “dead tank” type design current transformer.

FIG. 3 depicts a diagram of the present invention wherein a current image is relayed between two electronic circuits by a fiber optic conveyance and through an internalized interface for further transmittance.

And while the invention itself and method of use are amendable to various modifications and alternative configurations, specific embodiments thereof have been shown by way of example in the drawings and are herein described in adequate detail to inform those having skill in the art to make and practice the same. It should, however, be understood that the above description and preferred embodiments disclosed are not intended, and should not, limit the invention to the particular embodiment disclosed, but on the contrary, the invention disclosure is intended to cover all modifications, equivalents, and alternatives falling within the spirit and scope of the invention as defined within the claim's broadest reasonable interpretation consistent with the specification.

### DETAILED DESCRIPTION OF THE PREFERRED EMBODIMENTS

Advantages of the present invention will become readily apparent to those skilled in the art from the following detailed description, wherein there is described in detail certain preferred embodiments of the present invention (and examples for illustrative purposes). Although the following detailed description contains many specific features for the purposes of illustration, one of ordinary skill in the art will appreciate that many variations, modificaitons and alterations to the following details are within the scope of the invention. Accordingly, the following embodiments of the invention are set forth without any loss of generality to, and without imposing limitations upon, the claimed invention. While embodiments are described in connection with the specification herein, there is no intent to limit the scope to the embodiments disclosed below. On the contrary, the intent is to cover all alternatives, modifications, and equivalents.

Equally, it should be observed that the present invention can be understood, in terms of both structure and function, from the accompanying disclosure and claims taken in context with the associated drawings. And whereas the present invention and method of use are capable of several different embodiments, which can be arranged and rearranged into several configurations, which allows for mixing and matching of features and components, each exhibiting their accompanying interchanging functionalities, without departing from the scope and spirit of the present application.

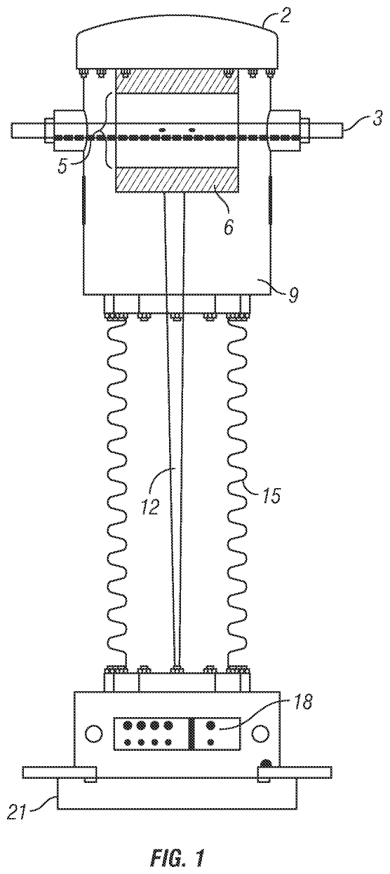

FIG. 1 illustrates the current state of technology of live tank design wherein the output of the secondary winding, relative to the current in the primary winding, is detected and transmitted via an analog conveyance where instruments and controlling devices receive a considerably smaller range of currents in relation to the large currents travelling through the primary winding.

Expressly, the structural representational diagram depicts a primary winding 3 that is made to translocate through the middle of the core 5 of the toroidal accepting structure and affixed secondary winding 6 which is housed within the upper live tank 9 of the “live tank design” current transformer 2 that represents the existing state of current transformer design. The primary current travelling through the primary winding 3 produces an alternating magnetic field within the core 5 which in turn induces an alternating current within the secondary winding 6 to produce a greatly reduced secondary current that may be several orders of magnitude decreased when interpreted by an ammeter (not shown). The current magnitude is then conveyed via an analog conveyance 12, through the live tank insulation 9 and CT bushing 15, wherein the secondary current is transmitted and relayed to the secondary terminal box 18 for subsequent transmittal to an external recording or monitoring device (not shown).

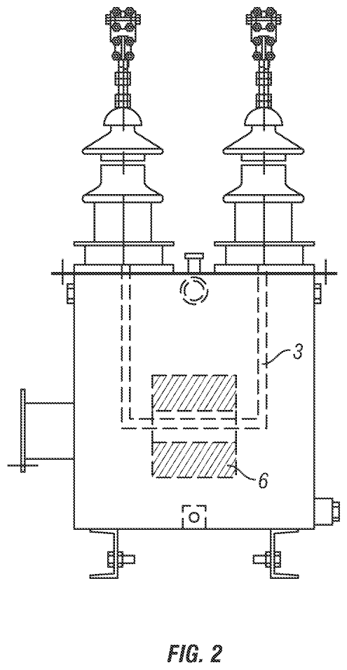

FIG. 2 illustrates the present invention that is the current transformer with a fiber optic mode and electronic circuit which is integrated into a dead tank type design wherein the primary 3 is “read” by the secondary winding 6 where data is transferred via a fiber optic conveyance to a receiving and transmitting device for relay to a technician or operator. Although structurally disparate from the live tank design in the areas of configuration and design, the conveyance of received data, in terms of secondary winding 6 output, can nonetheless benefit from a fiber optic conveyance of current data without succumbing to the above-mentioned infirmities.

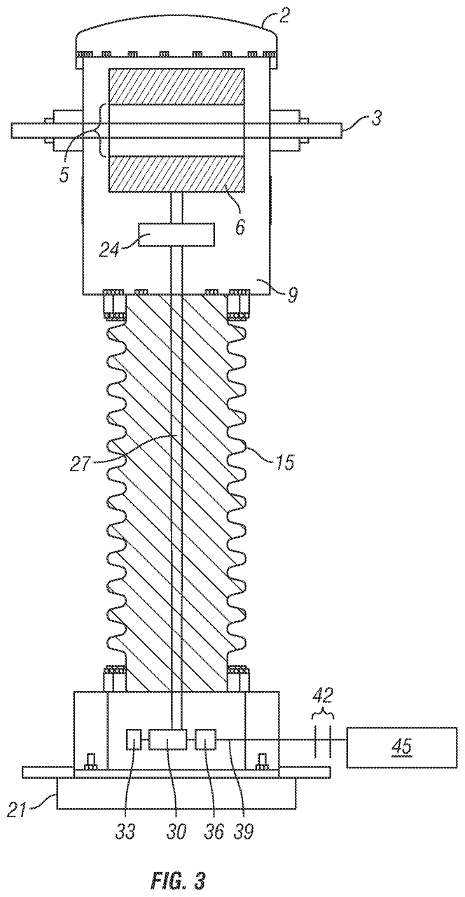

FIG. 3 depicts currents generated in the primary winding 3 where the energized primary winding 3 produces a magnetic field in the core 5 of the secondary winding 6 and the subsequent electromagnetic field drives the current in the secondary winding 6 which is relationally determinable to calculate the current in the primary winding 3 (via the transformation ratio). By knowing the secondary winding 6 ammeter current and actual current ratios (ratio of the number of primary to secondary turns), the current is easily determinable. And while the primary winding 3 is connected directly in series with the power circuit, the primary winding 3 is nonetheless separated and independent of the secondary current in the secondary winding 6.

As the primary winding 3 passes through the upper shell 9 of the live tank design and equally centrally through the middle of the toroidal core 5, the current passing through the annular open space of the secondary winding 6 generates a received current that is (1) physically separated from the current generated in the primary winding 3 and (2) is at a greatly decreased current relative to the current in the primary winding 3 (as is exhibited as a ratio of the primary current to secondary current). The current in the secondary winding 6 is then received and converted to a digital (digitized) signal via electronic circuitry 24 which then transmits the digitized data, via a fiber optic conveyance 27, to a reciprocating secondary electronic circuitry 30 in the secondary terminal box 21 wherein data is received and transmitted, via interface RJ 45 36 and interface RJ 432 39, to an external computer 45. Within the secondary terminal box 21 is housed an optional auxiliary power supply 33 which is tasked with facilitating the reception, processing and retransmission of received input from electronic circuitry 24, from electronic circuitry 30 via fiber optic conveyance 27, for the further transmittance via interface RJ 45 36 and interface RJ 432 39, respectively of secondary winding 6 data. This digitalized data is then conveyed to computer 45, then to any one to a number of interfaces 42 including a wireless, optical or digital communication interface (e.g. a wireless, GSM, optical or digital interface for delayed or contemporaneous transmittal to an exterior computer or computer system for receiving, monitoring, processing and storage of digitized information).

The particular embodiments disclosed are merely illustrative, which may be apparent to those having skill in the art that may be modified in diverse but equivalent manners. It is therefore contemplated that these particular embodiments may be altered and modified and that all such alterations are considered within the scope and spirit of the present application. And while these illustrations are of a limited number set, it is clear that the invention itself is mutable to any number of arrangements, configurations and modifications without departing from the invention's spirit thereof.

I claim:

1. A current transformer metering and monitoring system comprising:
a primary current in a primary winding;
a secondary winding for determining the primary current magnitude;
a primary electronic circuit for receipt of said primary current magnitude information;
a fiber optic conveyance for transmittal of said primary current magnitude information;
a secondary electronic circuit for receiving and processing of primary current magnitude information from said fiber optic conveyance;
an interface for transmittal of received said secondary current magnitude information externally; and
a computer for reception of current magnitude information.

2. The current transformer metering and monitoring system of claim 1, wherein the secondary winding determines the current in the primary winding, as a function of the ratio of turns of the secondary winding to the primary winding, wherein the current data is determined in said secondary winding, data is received by said primary electronic circuit, data is converted to digitized information for transmittal along said fiber optic conveyance, data is received by a secondary electronic circuit, data is then transmitted along an integrated interface to a wireless, optical or digital interface to an external computer for data collection, observation, interpretation, measurement, monitoring and power supply operation.

3. The current transformer metering and monitoring system of claim 2, wherein said digitized information is transmitted along a said fiber optic conveyance which allows for current readings from very low to very high magnitudes, requires no calibration or recalibration, can accommodate both AC and DC currents, is light and configurable and offers current measurements that are more accurate than analog measurements.

4. The current transformer metering and monitoring system of claim 1, wherein said secondary winding data, as a function of primary winding data, is received and conveyed via a primary electronic circuit-fiber optic conveyance-secondary electronic circuit system communicating with said interface or interfaces for transmittal of information to an additional interface, a series of interfaces, or directly to an external computer or plurality of computers.

5. The current transformer metering and monitoring system of claim 4, wherein said interface is an RJ-45 type interface, RS-232 type interface, RJ-432 type interface or RS-485 type interface for the relaying of information to an external receiver.

6. The current transformer metering and monitoring system of claim 4, wherein there exists said interface, in the form of a wireless, GSM, optical or digital interface for contemporaneous transmittal to an exterior receiver computer, computers or computer system for receiving, monitoring, analysis, processing and storage of digitized information.

7. The current transformer metering and monitoring system of claim 1 wherein, the secondary electronic circuit may be operated on a power supply that is axillary or self-powered by a conventional battery, a rechargeable battery or may be integrated into the existing electrical system or electric grid for power supply.

8. The current transformer metering and monitoring system of claim 1, wherein the present invention that is a current transformer is capable of detecting, monitoring and conveying current data of both AC and DC current.

9. The current transformer metering and monitoring system of claim 1, wherein the configuration of the current transformer may be of a live tank or dead tank design.

10. The current transformer metering and monitoring system of claim 1, wherein said fiber optic conveyance can be integrated into an existing current transformer or installed into a new current transformer wherein said fiber optic conveyance overcomes analog issues in flexibility of configuration and signal distortion, signal aberration, signal loss over long distances, tank weight and tank safety.

11. The current transformer metering and monitoring system of claim 1, wherein an individual current transformer may be used in series or combination with other individual current transformers or where said individual current transformer may be used to detect, monitor and convey multiple currents simultaneously, contemporaneously or sequentially thereby multiplying the effectiveness of each current transformer's limited error rate in aggregate and in sum.

12. The current transformer metering and monitoring system of claim 1, wherein an individual current transformer may be used in series or combination with other individual current transformers or wherein said individual current transformer may contain one to a plurality of electronic circuits and optic fiber conveyances, in various combinations, with which to collect, convey and transmit data.

13. The current transformer metering and monitoring system of claim 1, wherein said system may utilize the aforementioned electronic circuits, digitized information and fiber optic conveyances in current sensing, measurement, monitoring, and transmittance of information to an external computer for data collection, interpretation, and analysis but also may utilize the same avenues, retrograde, where information is sent from an external computer to the current transformer for instrument or system diagnostics, control, adjustments, updates and the like.

14. A method of monitoring the current in a primary winding comprising the steps of:
monitoring and measuring a primary current by a secondary winding;
receiving and interpreting the output of the secondary winding, as a function of the primary winding, by the primary electronic circuitry;
processing and digitizing analog information in the primary electronic circuit;
transmitting the digitized information via a fiber optic conveyance to a secondary electronic circuit;
receiving and processing digitized information in said electronic secondary circuit;
transferring the digitized information from said secondary electronic circuit via an interface or interfaces to a receiving computer, or computers, for monitoring, analysis and storage.

15. The method of claim 14 wherein the components of the monitoring system may be integrated into a live tank or dead tank design.

16. The method of claim 14 wherein the system can be made to measure either AC current, DC current or both at both high current magnitudes and low current magnitudes.

17. The method of claim 14 wherein said digitalized information is transported along and within the length of the neck of the live tank current transformer where the primary electronic circuitry is located in the primary terminal box of the live tank current transformer, the fiber optic conveyance is located in the neck of the live tank current transformer and said secondary electronic circuit is located in the secondary terminal box of the live tank current transformer.

18. The method of claim 14 wherein the interface or plurality of interfaces responsible for the transport of digitized information from the secondary electronic circuit to an externalized computer are located within the secondary terminal box of the live tank current transformer.

19. The method of claim 14 wherein the secondary electronic circuit may be operated on a power supply that is axillary or self powered by a traditional battery, via a rechargeable battery or may be integrated into the existing electrical system or electric grid.

20. The method of claim 14 wherein the digitalized information may be received, collected and transmitted via a wireless, GSM, optical or digital interface for delayed or contemporaneous transmittal to an exterior computer or computer system for receiving, monitoring, processing and storage of digitized information.

21. The method of claim 14 wherein the electronic circuits and fiber optic conveyance may include a plurality of electronic circuits and fiber optic conveyances, in various combinations, wherein said digitized secondary information is transmitted along said fiber optic conveyance, or plurality of fiber optic conveyances, which are easily flexible, modifiable and configurable and amendable to large increases in distance which allows for current readings from very low to very high magnitudes, requires no calibration or recalibration, can accommodate both AC and DC currents, offers current measurements that are more accurate than analog measurements in a configuration that is lighter, more compact, safer, more cost efficient and more environmentally conscious.

22. The method of claim 14 wherein information may be sent from a current transformer to an external computer, or plurality of computers, for monitoring, interpretation and analysis and information may be sent from said computer, or plurality of computers, to the current transformer for instrument or system diagnostics, control, adjustments, updates and the like.
